(19) United States
(12) Patent Application Publication
(10) Pub. No.: US 2006/0238257 A1
(43) Pub. Date: Oct. 26, 2006

(54) Control of transmission power in a mobile station

(75) Inventor: Dong-Ho Han, Gyeonggi-do (KR)

Correspondence Address: JONATHAN Y. KANG, ESQ.;LEE, HONG, DEGERMAN, KANG & SCHMADEKA, P.C., 14th Floor, 801 S. Figueroa Street, Los Angeles, CA, 90017-5554, US

(73) Assignee: LG Electronics Inc.

(21) Appl. No.: 11/341,989

(22) Filed: Jan. 27, 2006

(30) Foreign Application Priority Data
Jan. 27, 2005 (KR) 10-2005-0007678

(51) Int. Cl. H03F 3/04

(52) U.S. Cl. 330/289

(57) ABSTRACT

An apparatus adapted to control transmission power in a mobile station comprises a power amplifier adapted to amplify a radio signal with a gain characteristic corresponding to a computed transmission level, and an automatic gain control unit adapted to generate an automatic gain control signal to control a gain of the power amplifier. The apparatus also comprises a temperature compensating unit adapted to compute a maximum output deviation of the mobile station according to a temperature variation of the power amplifier, the temperature compensating unit compensating the automatic gain control signal using a per temperature compensating value according to the computed deviations. The apparatus also comprises a control unit adapted to control the automatic gain control unit and the temperature compensating unit by sensing the temperature variation of the power amplifier and by detecting an output characteristic of the power amplifier according to the temperature variation.

### CROSS-REFERENCE TO RELATED APPLICATIONS

Pursuant to 35 U.S.C. § 119(a), this application claims the benefit of earlier filing date and right of priority to Korean Application No. 2005-0007678, filed on Jan. 27, 2005, the content of which are hereby incorporated by reference herein in their entirety.

### FIELD OF THE INVENTION

The present invention relates generally to a mobile station and, more particularly, to transmission power control in a mobile station.

### BACKGROUND OF THE INVENTION

Generally, a mobile station accesses a base station in a corresponding service area according to a wireless communication system and maintains a communication state while moving to enable communication with another mobile station. The mobile station maintains a wireless access state with the base station based on operational characteristics of the mobile station to confirm a direction in which the mobile station is moving and a distance from the mobile station to the base station. To maintain uniform communication sensitivity, a power level of the mobile station should be maintained at a constant level.

A mobile station according to a related art controls a power level of a transmission signal according to a distance variation from a base station. Such a transmission power control of the mobile station shows non-linear characteristics according to a configuration circuit, temperature variation and usable frequency band of the mobile station. The mobile station computes a compensating value according to a temperature variation such that a compensated transmission signal may be transmitted at a specific power level. The mobile station then stores a value for a temperature compensation to use in transmission power control.

The mobile station performs RF transmission compensation and/or temperature compensation to control the power level of the transmission signal. The mobile station computes a transmission level of an RF signal in a manner that a communication module detects a level of an RF reception signal. Subsequently, by controlling a corresponding automatic gain control signal (AGC) for transmission, an output of the RF signal is delivered to an antenna. The output is called a terminal output characteristic.

The RF signal, which is generated from the communication module, varies according to internal circuit characteristics until being transferred to the antenna that is an output end. To compensate for this, the mobile station uses an output automatic gain control signal (AGC). This operation is called a RF transmission compensation of a terminal and the corresponding value is called a RF transmission compensating value.

After a transmission level of the RF signal has been computed by detecting the level of the RF reception signal, the corresponding transmission automatic gain control signal (AGC) is controlled. In so doing, RF transmission is carried out in a manner of uniformly adding and/or subtracting a per temperature compensating value amounting to a difference of a maximum output according to the temperature variation to and/or from an RF transmission maximum output and an automatic gain control signal. This operation is called a temperature compensation.

In a temperature compensating method according to a related art, a per temperature compensating value is determined one by one in a manner of applying compensating values according to a temperature variation (−30˜60° C.) to a prescribed sample terminal, through a trial and error process. Thus, the related art method requires significant time and effort to compute the compensating value.

A mean value of the compensating values per temperature is collectively applied to the compensating value for the transmission signal of the mobile station. Since an output characteristic of a power amplifier having a large characteristic variation according to a temperature is not taken into consideration, an output error of a transmission signal becomes considerable, and results in another problem of the related art method.

Furthermore, since the related art compensating method must re-compute all values from the beginning to apply in case of altering a configurational circuit or printed circuit board (PCB) of the mobile station, additional time and effort are consumed.

### SUMMARY OF THE INVENTION

Accordingly, the present invention is directed to control of transmission power in a mobile station that substantially obviates one or more problems due to limitations and disadvantages of the related art.

An object of the present invention is to provide for temperature compensation in a mobile station according to a per temperature output characteristic of a power amplifier, by which an error of a transmission signal is reduced by detecting the per temperature output characteristic of the power amplifier to control a power level of a transmission signal variable according to a temperature variation and by computing a temperature compensation value of the mobile station and by which a temperature compensation value computation is facilitated even if a configuration circuit of the mobile station is varied.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, in one embodiment, an apparatus adapted to control transmission power in a mobile station comprises a power amplifier adapted to amplify a radio signal with a gain characteristic corresponding to a computed transmission level, and an automatic gain control unit adapted to generate an automatic gain control signal to control a gain of the power amplifier. The apparatus also comprises a temperature compensating unit adapted to compute a maximum output deviation of the mobile station according to a temperature variation of the power amplifier, the temperature compensating unit compensating the automatic gain control signal using a per temperature compensating value according to the computed deviations. The apparatus also comprises a control unit adapted to control the automatic gain control unit and the temperature compensating unit by sensing the temperature variation of the power amplifier and by detecting an output characteristic of the power amplifier according to the temperature variation.

The apparatus may further comprise a memory adapted to store a per temperature output characteristic of the power amplifier and per temperature maximum output deviation information of the mobile station. The temperature compensating unit may comprise means for detecting a per temperature output characteristic (Ft (1˜8)) of the power amplifier, means for computing a per temperature maximum output deviation (Pdt (1˜8)) of the mobile station based on the detecting the per temperature output characteristic, means for finding a deviation (Adt (1˜8)) of an automatic gain control signal according to the per temperature maximum output deviation of the mobile station, means for computing a temperature compensating value (A (1˜8)) according to the deviation of the automatic gain control signal, and means for amplifying to transmit a radio signal by controlling the power amplifier according to the automatic gain control signal to which the temperature compensating value (A (1˜8)) is applied. The means for computing the per temperature maximum output deviation may comprise means for computing an output value (Ptm) at a room temperature, means for detecting a per temperature output value (Pt (1˜8) of the mobile station, and means for computing a maximum output deviation (Pdt) of the mobile station according to a temperature variation by subtracting the per temperature output value (Pt (1˜8)) of the mobile station from the output value (Ptm) at the room temperature.

In another embodiment, a method for controlling transmission power in a mobile station comprises compensating an output automatic gain control signal by reflecting an output characteristic of a power amplifier according to a temperature variation and an error value of a per temperature maximum output, and controlling transmission power in the mobile station based on the compensating of the output automatic gain control signal.

A temperature range of −30° C. to 60° C. may be divided into eight temperature steps, and a temperature compensating value may be computed for each of the eight temperature steps. The method may further comprise a first step of detecting a per temperature output characteristic (Ft (1˜8)) of the power amplifier, a second step of computing a per temperature maximum output deviation (Pdt (1˜8)) of the mobile station according to a result of the first step, a third step of finding a deviation (Adt (1˜8)) of an automatic gain control signal according to the per temperature maximum output deviation of the mobile station, a fourth step of computing a temperature compensating value (A (1˜8)) according to the deviation of the automatic gain control signal, and a fifth step of amplifying to transmit a radio signal by controlling the power amplifier according to the automatic gain control signal to which the temperature compensating value (A (1˜8)) is applied. The method may further comprise returning to the third step if at least one of a configuration circuit and a printed circuit board belonging to the mobile station is altered. In the first step, a relationship between the automatic gain control signal and an output at each temperature may be measured for computation. The second step may comprise a first sub-step of computing an output value (Ptm) at a room temperature, a second sub-step of detecting a per temperature output value (Pt (1˜8) of the mobile station, and a third sub-step of computing a maximum output deviation (Pdt) of the mobile station according to a temperature variation by subtracting the per temperature output value (Pt (1˜8)) of the mobile station from the output value (Ptm) at the room temperature. In the first sub-step, the output value (Ptm) at the room temperature may reflect an output characteristic (Ftm) of the power amplifier in a state corresponding to a maximum output automatic gain control signal value (Atm) at the room temperature. In the third step, the deviation (Adt (1˜8)) of the automatic gain control signal may be computed by reflecting a per temperature maximum output deviation (Pdt (1˜8)) of the mobile station and a per temperature output characteristic (Ft (1˜8)) of the power amplifier. In the fourth step, a per temperature automatic gain control signal compensating value (A (1˜8)) may be computed by adding the per temperature automatic gain control signal deviation (Adt (1˜8)) and the automatic gain control signal value (Atm) at the room temperature. In the fifth step, a transmission signal may be compensated by applying the temperature compensating value (A (1˜8)) per temperature to the automatic gain control signal and by allowing the power amplifier to amplify the signal by the compensated automatic gain control signal.

The foregoing and other objects, features, aspects and advantages of the present invention will become more apparent from the following detailed description of the present invention when taken in conjunction with the accompanying drawings. It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principles of the invention.

FIG. 1 is a block diagram illustrating a mobile station, according to an embodiment of the present invention.

FIG. 2 is a graph illustrating an output characteristic of an amplifier of a mobile station, according to an embodiment of the present invention.

FIG. 3 is a flow diagram illustrating a temperature compensating method in a mobile station, according to an embodiment of the present invention.

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

There are various types of mobile stations, including mobile phones, handsets, PDAs (personal digital assistants), and computers, as well as any other devices with wireless communication capabilities. A mobile station may also be referred to as a mobile terminal or a terminal. Control of transmission power in a mobile station is described below.

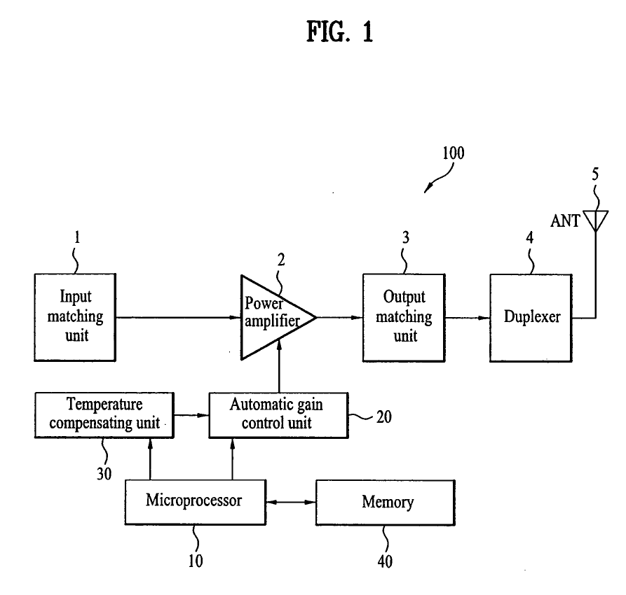

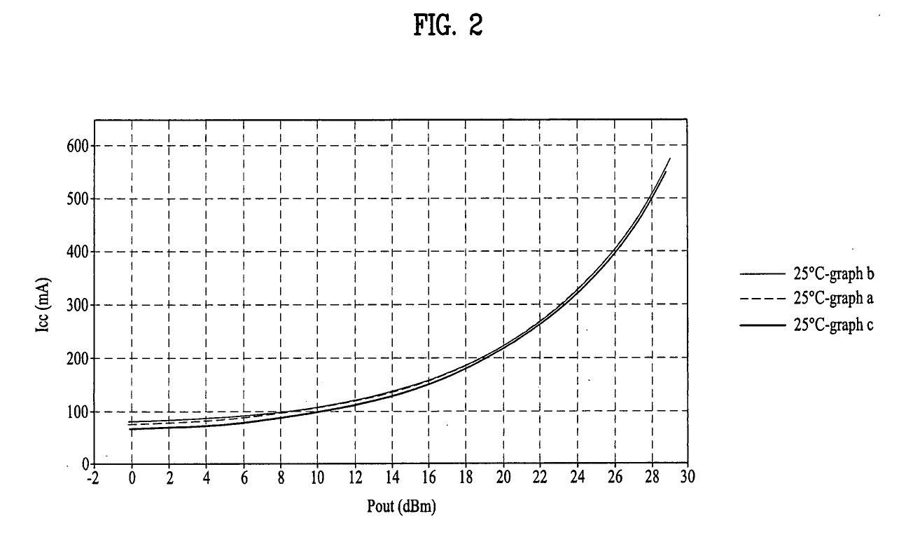

FIG. 1 is a block diagram illustrating a mobile station 100, according to an embodiment of the present invention. FIG. 2 is a graph illustrating an output characteristic of an amplifier of a mobile station, according to an embodiment of the present invention.

Referring to FIG. 1, the mobile station 100, which computes a temperature compensating value according to an output characteristic of a power amplifier, includes a power amplifier 2 for amplifying a signal supplied via an input matching unit 1 with a gain characteristic, an automatic gain control unit 20 for generating an automatic gain control signal for controlling a gain of the power amplifier 2, and a temperature compensating unit 30 for compensating the automatic gain control signal by computing a per temperature compensating value according to a temperature variation of the power amplifier 2.

The mobile station 100 further includes a microprocessor 10 for generating a signal to be delivered to the input matching unit 1, and for enabling a transmission signal amplified by the power amplifier 1 to be matched via an output matching unit 3 to be transferred to an antenna 5 via a duplexer 4. The microprocessor 10 also controls the automatic gain control unit 20 and the temperature compensating unit 30. A memory 40 is coupled to the microprocessor 10, to provide data storage capacity to the microprocessor 10. For example, the memory 40 may store a per temperature output characteristic of the power amplifier and per temperature maximum output deviation information of the mobile station 100.

The microprocessor 10 senses the temperature variation of the power amplifier 2 and detects the output characteristic of the power amplifier 2 according to the temperature variation. In so doing, the microprocessor 10 divides a temperature range of −30˜60° C. into eight steps to detect the output characteristics according to the steps, respectively. The output characteristic of the power amplifier 2, as shown in FIG. 2, is varied according to the temperature. Referring to FIG. 2, graph-a represents an output characteristic of the power amplifier 2 according to an input current at a low temperature of −30° C. Graph-c represents an output characteristic of the power amplifier 2 according to an input current at a room temperature, and an output characteristic of the power amplifier 2 according to an input current at a high temperature of 85° C. For example, when the input current of the power amplifier 2 is 100 mA, if the graph-b at 25° C. and the graph-c at 85° C. are compared to each other, there exists an output difference of about 1.5 dBm at −30° C. over the room temperature or an output difference of about 1 dBm at 85° C. over the room temperature. In such case, the microprocessor 10 detects the output characteristics, as shown in FIG. 2, of the power amplifier 2 per the temperature step and then transfers the detected output characteristics to the temperature compensating unit 20 to compensate the variation of the output characteristic according to the temperature.

The microprocessor 10 detects the output characteristic of the power amplifier 2 at the room temperature, an output characteristic of the mobile station at the room temperature and the automatic gain control signal at the room temperature by the automatic gain control unit 20. The automatic gain control unit 20 computes a level of a signal to be transmitted according to a location, a usable frequency band, and/or a temperature of the mobile station and then transfers the automatic gain control signal to the power amplifier 2 to amplify the signal according to the computed signal level.

The temperature compensating unit 30 computes the temperature compensating value according to each temperature level to correspond to the output characteristic value transferred from the microprocessor 10. In such case, the temperature compensating unit 30 analyzes a characteristic value according to each temperature step by the microprocessor 10. The temperature compensating unit 30 also computes a corresponding maximum output deviation of the mobile station per temperature and a corresponding deviation of the automatic gain control signal, and then correspondingly computes the temperature compensating value per temperature.

The temperature compensating unit 30 transfers the computed temperature compensating value to the automatic gain control unit 20. The automatic gain control unit 20 applies the temperature compensating value to the automatic gain control signal to transfer the compensated automatic gain control signal to the power amplifier 2. Hence, a compensated transmission signal may be transmitted via the antenna 5.

The mobile station computes the temperature compensating value by considering variations of the output characteristic according to the temperature variation of the power amplifier 2. Hence, the mobile station may reduce error of the signal transmitted via the antenna. In a case where the temperature compensating value is re-computed, such as when the configuration circuit of the mobile station is variable, the deviation computation of the temperature compensating unit 30 facilitates the computation of the temperature compensating value.

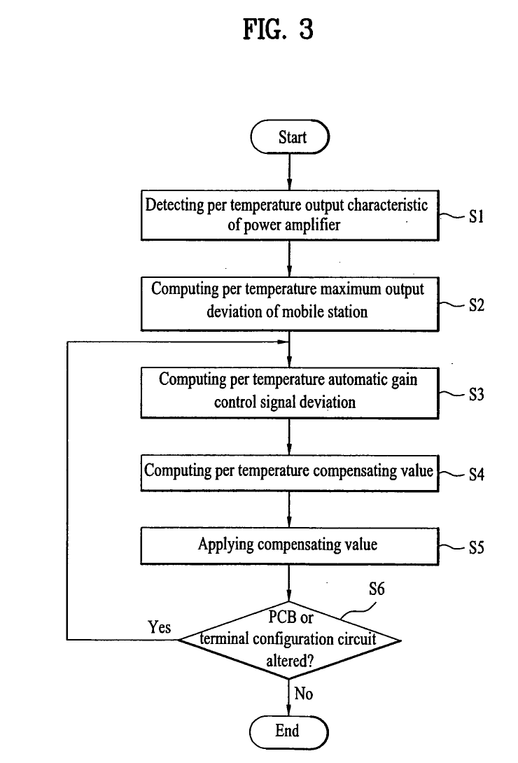

FIG. 3 is a flow diagram illustrating a temperature compensating method in a mobile station, according to an embodiment of the present invention.

The following definitions apply to the method described with reference to FIG. 3, below. Atm is a maximum output automatic gain control value at a room temperature. Adt is an automatic gain control signal deviation value generated from a per temperature output difference. A (1˜8) is a per temperature output automatic gain control signal compensating value. Ft(1˜8) is a per temperature output characteristic. Ftm( ) is an output characteristic at a room temperature. Pdt(1˜8) is a per temperature output error value (dBm). Pt(1˜8) is a per temperature output value (dBm). Ptm is an output at a room temperature

A per temperature output characteristic according to each temperature step of the power amplifier is detected, and an output characteristic of the power amplifier at the room temperature is also detected. By varying the temperature at the same output condition, the characteristic Ft (1˜8) of the power amplifier may be detected. As such, by dividing a temperature range of −30˜60 into eight steps, the output characteristic of the power amplifier per temperature according to each of the temperature steps may be detected. The detected per temperature output characteristic of the power amplifier is separately stored in a memory to be re-utilized in re-computing the temperature compensating value.

The output characteristic of the power amplifier may be detected using a formula of ‘P=F (A)’ according to an output value. In such case, ‘P’ is a terminal output, ‘F’ is a power amplifier output characteristic, and ‘A’ is an automatic gain signal. Thus, the per temperature output characteristic of the power amplifier and the output characteristic of the power amplifier at the room temperature may be detected using a measured output value of the mobile station. The formula may be used inversely according to the measured automatic gain control signal of the mobile station (S1).

According to the transmission signal transmitted via the antenna after being amplified by the power amplifier, a maximum output detection (P) of the mobile station and the corresponding deviation (Pdt) are computed. As such, according to the detected output characteristic (Ft) of the power amplifier, the per temperature maximum output deviation (Pdt (1˜8)) of the mobile station may be computed. In such case, the value of Atm that is not compensated is used in computing the per temperature maximum output deviation (Pdt (1˜8)) of the mobile station.

The above assertions may be expressed in the below exemplary formulas:
Pt(1˜8)=Ftm(Atm)
Ptm=Ftm(Atm)
Pdt(1˜8)=Ptm−Pt(1˜8)

The per temperature maximum output of the mobile station may be detected using the automatic gain control signal and the per temperature output characteristic of the power amplifier. A value of the automatic gain control signal, which controls a gain of the power amplifier, at the room temperature is detected. Moreover, the maximum output value of the mobile station at the room temperature is detected using the output characteristic value of the power amplifier at the room temperature and the value of the automatic gain control signal at the room temperature.

By subtracting the per temperature maximum output of the mobile station from the maximum output of the mobile station at the room temperature, a per temperature maximum output deviation of the mobile station is computed. As such, the per temperature maximum output deviation of the mobile station may be computed using the uncompensated value (S2). The per temperature deviation (Adt (1˜8)) of the automatic gain control signal may be computed using the computed maximum output deviation (Pdt (1˜8) of the mobile station inversely.

The above assertions may be expressed in the below exemplary formulas:
Pdt(1˜8)=Ft(1˜8)(Adt(1˜8)).
Hence, Adt(118)=Ft(1˜8)⁻¹(Pdt(1˜8))

That is, the per temperature deviation of the automatic gain control signal may be computed using an inverse function of the per temperature output characteristic of the power amplifier and the maximum output deviation of the mobile station (S3).

The temperature compensating value of the automatic gain control signal is computed by adding together the deviation value of the per temperature automatic gain control signal and the automatic gain control signal at the room temperature. The transmission signal may thus be compensated by adding the computed temperature compensating value of the automatic gain control signal to the automatic gain control signal. Thus, the compensating value may be computed using the formula of ‘A (1˜8)=Atm+Adt (1˜8)’ (S4), for example. The signal to be transmitted may be controlled by applying the above computed per temperature compensating value to the automatic gain control signal according to each temperature (S5), for example.

In a case where the configuration circuit, printed circuit board (PCB), and/or material is varied during manufacturing of the mobile station, the corresponding temperature compensating value may be re-computed (S6). When re-computing the temperature compensating value due to a variable circuit configuration and/or material of the mobile station, instead of computing the temperature compensating value according to the mobile station, the deviation of the automatic gain control signal of the mobile station may be re-computed using the previously-stored per temperature output characteristic of the power amplifier and the maximum output deviation of the mobile station. Thus, by repetition of procedures for computing the automatic gain control signal and the corresponding compensating value, a new temperature compensating value of the mobile station may be computed (S3 to S5).

In one embodiment, an apparatus adapted to control transmission power in a mobile station comprises a power amplifier adapted to amplify a radio signal with a gain characteristic corresponding to a computed transmission level, and an automatic gain control unit adapted to generate an automatic gain control signal to control a gain of the power amplifier. The apparatus also comprises a temperature compensating unit adapted to compute a maximum output deviation of the mobile station according to a temperature variation of the power amplifier, the temperature compensating unit compensating the automatic gain control signal using a per temperature compensating value according to the computed deviations. The apparatus also comprises a control unit adapted to control the automatic gain control unit and the temperature compensating unit by sensing the temperature variation of the power amplifier and by detecting an output characteristic of the power amplifier according to the temperature variation.

The apparatus may further comprise a memory adapted to store a per temperature output characteristic of the power amplifier and per temperature maximum output deviation information of the mobile station. The temperature compensating unit may comprise means for detecting a per temperature output characteristic (Ft (1˜8)) of the power amplifier, means for computing a per temperature maximum output deviation (Pdt (1˜8)) of the mobile station based on the detecting the per temperature output characteristic, means for finding a deviation (Adt (1˜8)) of an automatic gain control signal according to the per temperature maximum output deviation of the mobile station, means for computing a temperature compensating value (A (1˜8)) according to the deviation of the automatic gain control signal, and means for amplifying to transmit a radio signal by controlling the power amplifier according to the automatic gain control signal to which the temperature compensating value (A (1˜8)) is applied. The means for computing the per temperature maximum output deviation may comprise means for computing an output value (Ptm) at a room temperature, means for detecting a per temperature output value (Pt (1˜8) of the mobile station, and means for computing a maximum output deviation (Pdt) of the mobile station according to a temperature variation by subtracting the per temperature output value (Pt (1˜8)) of the mobile station from the output value (Ptm) at the room temperature.

In another embodiment, a method for controlling transmission power in a mobile station comprises compensating an output automatic gain control signal by reflecting an output characteristic of a power amplifier according to a temperature variation and an error value of a per temperature maximum output, and controlling transmission power in the mobile station based on the compensating of the output automatic gain control signal.

A temperature range of −30° C. to 60° C. may be divided into eight temperature steps, and a temperature compensating value may be computed for each of the eight temperature steps. The method may further comprise a first step of detecting a per temperature output characteristic (Ft (1˜8)) of the power amplifier, a second step of computing a per temperature maximum output deviation (Pdt (1˜8)) of the mobile station according to a result of the first step, a third step of finding a deviation (Adt (1˜8)) of an automatic gain control signal according to the per temperature maximum output deviation of the mobile station, a fourth step of computing a temperature compensating value (A (1˜8)) according to the deviation of the automatic gain control signal, and a fifth step of amplifying to transmit a radio signal by controlling the power amplifier according to the automatic gain control signal to which the temperature compensating value (A (1˜8)) is applied. The method may further comprise returning to the third step if at least one of a configuration circuit and a printed circuit board belonging to the mobile station is altered. In the first step, a relationship between the automatic gain control signal and an output at each temperature may be measured for computation. The second step may comprise a first sub-step of computing an output value (Ptm) at a room temperature, a second sub-step of detecting a per temperature output value (Pt (1˜8) of the mobile station, and a third sub-step of computing a maximum output deviation (Pdt) of the mobile station according to a temperature variation by subtracting the per temperature output value (Pt (1˜8)) of the mobile station from the output value (Ptm) at the room temperature. In the first sub-step, the output value (Ptm) at the room temperature may reflect an output characteristic (Ftm) of the power amplifier in a state corresponding to a maximum output automatic gain control signal value (Atm) at the room temperature. In the third step, the deviation (Adt (1˜8)) of the automatic gain control signal may be computed by reflecting a per temperature maximum output deviation (Pdt (1˜8)) of the mobile station and a per temperature output characteristic (Ft (1˜8)) of the power amplifier. In the fourth step, a per temperature automatic gain control signal compensating value (A (1˜8)) may be computed by adding the per temperature automatic gain control signal deviation (Adt (1˜8)) and the automatic gain control signal value (Atm) at the room temperature. In the fifth step, a transmission signal may be compensated by applying the temperature compensating value (A (1˜8)) per temperature to the automatic gain control signal and by allowing the power amplifier to amplify the signal by the compensated automatic gain control signal.

Accordingly, the present invention has several advantages. In the transmission power control method in the mobile station according to the per temperature output characteristic of the power amplifier, the power level control of the transmission signal is facilitated by compensating the error of the transmission signal according to the temperature variation. This is because the temperature compensating value of the automatic gain control signal is computed by considering the per temperature output characteristic of the power amplifier of which output value is varied according to the temperature variation. Furthermore, in altering the configuration circuit and/or the material (e.g., PCB) of the mobile station, the present invention facilitates the re-computation of the temperature compensating value, thereby reducing the time, effort and cost for computing the temperature compensating value.

It will be apparent to those skilled in the art that various modifications and variations may be made in the present invention without departing from the spirit or scope of the inventions. Thus, it is intended that the present invention covers the modifications and variations of this invention provided they come within the scope of the appended claims and their equivalents.

What is claimed is:

1. An apparatus adapted to control transmission power in a mobile station, the apparatus comprising:
a power amplifier adapted to amplify a radio signal with a gain characteristic corresponding to a computed transmission level;
an automatic gain control unit adapted to generate an automatic gain control signal to control a gain of the power amplifier;
a temperature compensating unit adapted to compute a maximum output deviation of the mobile station according to a temperature variation of the power amplifier, the temperature compensating unit compensating the automatic gain control signal using a per temperature compensating value according to the computed deviations; and
a control unit adapted to control the automatic gain control unit and the temperature compensating unit by sensing the temperature variation of the power amplifier and by detecting an output characteristic of the power amplifier according to the temperature variation.

2. The apparatus of claim 1, further comprising:
a memory adapted to store a per temperature output characteristic of the power amplifier and per temperature maximum output deviation information of the mobile station.

3. The apparatus of claim 1, wherein the temperature compensating unit comprises:
means for detecting a per temperature output characteristic (Ft (1˜8)) of the power amplifier;
means for computing a per temperature maximum output deviation (Pdt (1˜8)) of the mobile station based on the detecting the per temperature output characteristic;
means for finding a deviation (Adt (1˜8)) of an automatic gain control signal according to the per temperature maximum output deviation of the mobile station;
means for computing a temperature compensating value (A (1˜8)) according to the deviation of the automatic gain control signal; and
means for amplifying to transmit a radio signal by controlling the power amplifier according to the automatic gain control signal to which the temperature compensating value (A (1˜8)) is applied.

4. The apparatus of claim 3, wherein the means for computing the per temperature maximum output deviation comprises:
means for computing an output value (Ptm) at a room temperature;
means for detecting a per temperature output value (Pt (1˜8) of the mobile station; and
means for computing a maximum output deviation (Pdt) of the mobile station according to a temperature variation by subtracting the per temperature output value (Pt (1˜8)) of the mobile station from the output value (Ptm) at the room temperature.

5. A method for controlling transmission power in a mobile station, the method comprising:
compensating an output automatic gain control signal by reflecting an output characteristic of a power amplifier according to a temperature variation and an error value of a per temperature maximum output; and
controlling transmission power in the mobile station based on the compensating of the output automatic gain control signal.

6. The method of claim 5, wherein a temperature range of −30° C. to 60° C. is divided into eight temperature steps, and wherein a temperature compensating value is computed for each of the eight temperature steps.

7. The method of claim 6, further comprising:
a first step of detecting a per temperature output characteristic (Ft (1˜8)) of the power amplifier;
a second step of computing a per temperature maximum output deviation (Pdt (1˜8)) of the mobile station according to a result of the first step;
a third step of finding a deviation (Adt (1˜8)) of an automatic gain control signal according to the per temperature maximum output deviation of the mobile station;
a fourth step of computing a temperature compensating value (A (1˜8)) according to the deviation of the automatic gain control signal; and
a fifth step of amplifying to transmit a radio signal by controlling the power amplifier according to the automatic gain control signal to which the temperature compensating value (A (1˜8)) is applied.

8. The method of claim 7, further comprising:
returning to the third step if at least one of a configuration circuit and a printed circuit board belonging to the mobile station is altered.

9. The method of claim 7, wherein in the first step, a relationship between the automatic gain control signal and an output at each temperature is measured for computation.

10. The method of claim 7, wherein the second step comprises:
a first sub-step of computing an output value (Ptm) at a room temperature;
a second sub-step of detecting a per temperature output value (Pt (1˜8) of the mobile station; and
a third sub-step of computing a maximum output deviation (Pdt) of the mobile station according to a temperature variation by subtracting the per temperature output value (Pt (1˜8)) of the mobile station from the output value (Ptm) at the room temperature.

11. The method of claim 10, wherein in the first sub-step, the output value (Ptm) at the room temperature reflects an output characteristic (Ftm) of the power amplifier in a state corresponding to a maximum output automatic gain control signal value (Atm) at the room temperature.

12. The method of claim 7, wherein in the third step, the deviation (Adt (1˜8)) of the automatic gain control signal is computed by reflecting a per temperature maximum output deviation (Pdt (1˜8)) of the mobile station and a per temperature output characteristic (Ft (1˜8)) of the power amplifier.

13. The method of claim 7, wherein in the fourth step, a per temperature automatic gain control signal compensating value (A (1˜8)) is computed by adding the per temperature automatic gain control signal deviation (Adt (1˜8)) and the automatic gain control signal value (Atm) at the room temperature.

14. The method of claim 7, wherein in the fifth step, a transmission signal is compensated by applying the temperature compensating value (A (1˜8)) per temperature to the automatic gain control signal and by allowing the power amplifier to amplify the signal by the compensated automatic gain control signal.
